(19) United States
(12) Patent Application Publication
(10) Pub. No.: US 2003/0057106 A1
(43) Pub. Date: Mar. 27, 2003

(54) High throughput chemical analysis by improved desorption/ionization on silicon mass spectrometry

(76) Inventors: Zhouxin Shen, San Diego, CA (US); Gary Siuzdak, San Diego, CA (US)

Correspondence Address: Welsh & Katz, Ltd., 22nd Floor, 120 South Riverside Plaza, Chicago, IL, 60606, US

(21) Appl. No.: 10/242,018

(22) Filed: Sep. 12, 2002

Related U.S. Application Data
(60) Provisional application No. 60/318,332, filed on Sep. 12, 2001.

(51) Int. Cl. B23H 3/00; C25F 3/00; H05K 3/07; B23H 5/00

(52) U.S. Cl. 205/655; 435/2; 436/177; 436/178

(57) ABSTRACT

A method of making improved substrates for desorbing and ionizing analytes takes an n-type semiconductor substrate and provides a strong light source. By focusing the illumination from the light source onto the n-type semiconductor substrate results in at least one lit region on the n-type semiconductor substrate. The substrate is electrochemically etched with a low current during illumination to form at least one sample reservoir, each sample reservoir being formed at a respective lit region on the n-type semiconductor substrate.

### CROSS REFERENCE TO RELATED APPLICATIONS

This application claims the benefit of priority to U.S. Provisional Application No. 60/312,332 filed on Sep. 12, 2001, which is incorporated by reference as if fully set forth herein.

### FEDERAL RESEARCH STATEMENT

This invention was made with government support under Grant No. RR15066 awarded by the National Institutes of Health. The U.S. government has certain rights in the invention.

### BACKGROUND OF THE INVENTION

The field of the subject invention is mass spectrometry and more particularly the invention pertains to the facilitation of high throughput mass spectrometry through improved desorption and ionization of an analyte from porous substrates that absorb light including, but not limited to, porous silicon.

The high-throughput analysis capabilities of mass spectrometry have received much attention in recent years, making a direct impact on such diverse areas as drug development (1,2), pharmacokinetics (3), proteomics (4,5), and catalyst discovery (6, 7). In the case of combinatorial chemistry, mass spectrometry is often the only analytical technique used, and in many circumstances can be the only feasible tool. Mass spectrometry provides high sensitivity without the requirement (11) for chromophoric or fluorophoric units or other conventional tags in the analyte, thereby offering an effective alternative or complement to techniques such as absorption spectroscopy (for example, infra-red absorption spectroscopy) and nuclear magnetic resonance spectroscopy (NMR). The solution-based approach of electrospray ionization (ESI) mass spectrometry has been a common method used for characterization, especially in combinatorial chemistry, largely because of its utility for a wide array of compounds and its potential for rapid data acquisition. However, ESI-MS is not a surface-based approach, and consequently does not provide the benefit of being able to scan a surface on which a large number of compounds have been deposited.

Currently, some believe that the most promising approaches for high-throughput mass analyses involve multiplexed (MUX) electrospray methods (8-9) and the surface-based matrix-assisted laser desorption/ionization (MALDI) mass spectrometry technique (10). The former allows for multiple liquid chromatography (LC) systems to be analyzed simultaneously by rapidly sampling multiple ESI sources on a single mass spectrometer. The limitations of the MUX-ESI-MS (9) method include cross-contamination caused by injecting different samples from the same source, and the somewhat fragile nature of multiplex systems having many working components that can render them unreliable or otherwise troublesome. MALDI-MS allows for scanning with robust equipment and little cross-contamination, but the use of matrix material makes small-molecule analysis problematic due to interference by matrix-derived ions. MALSI-MS is also problematic for high throughput applications because it is time-consuming due to the non-uniform crystallization of matrix material.

As illustrated in FIGS. 1-2, one embodiment of desorption and ionization from porous semiconductor substrates, Desorption/Ionization On Silicon (DIOS), employs pulsed laser desorption/ionization from a silicon surface (11-14) using MALDI instrumentation. Methods related to desorption and ionization from porous substrates that can absorb light to desorb and ionize analytes are described at some length in U.S. Pat. No. 6,288,390 to Siuzdak et al. Briefly, the porous silicon semiconductor material traps analytes deposited on the surface where pulsed laser radiation can be used to vaporize and ionize these molecules without the presence of matrix material. In contrast to what is typically observed with other direct desorption/ionization approaches, it has been observed that DIOS-MS can be used for a wide range of analytes at the picomole (pmol) to attomole (amol) level with little or no fragmentation. (13)

Generally, DIOS-MS offers good sensitivity, low background ion interference, and a high salt tolerance. The matrix-free approach is especially useful in the analysis of small molecules (mass to charge ratio, m/z, less than about 700), which typically encounter severe interference or suppression in MALDI-MS. The application of DIOS-MS to quantitative analysis, protein identification, protein functional analysis and post-source decay structural analysis has also been demonstrated. (13, 14) Implemented as a silicon-wafer based technology, DIOS-MS offers compatibility with microfluidics and microchip technology.

However, further improvements can be desired, especially in the area of achieving high throughput mass spectrometry results. If methods can be developed to yield improved regularity of the positioning of sample deposition reservoirs on the DIOS substrate can facilitate automation of experiments. Further reductions in low mass interference can improve already high sensitivity of the technique, opening the door to further applications. Also, if multi-component mixtures of organic chemicals can be studied accurately in an array format without the need for fluorophores, chromophores, separation technologies, or matrix material while preventing the cross-contamination of samples, a wide variety of useful assays would be greatly facilitated.

### SUMMARY OF THE INVENTION

The present invention relates to an improved method for manufacturing substrates to desorb and ionize analytes, especially biologically complex analytes, from a semiconductor substrate. It also relates to a method of assaying a plurality of analytes of samples including at least one protein or enzyme.

One method aspect of this invention contemplates a method for providing an improved substrate comprising the steps of:

providing an n-type semiconductor substrate;

providing a light source;

focusing the illumination from the light source onto the n-type semiconductor substrate to result in at least one lit region on the n-type semiconductor substrate; and

electrochemically etching the n-type semiconductor substrate with a low current during illumination to form at least one sample reservoir, each sample reservoir being formed at a respective lit region on the n-type semiconductor substrate.

In a preferred embodiment the substrate is n-type silicon.

In another embodiment of the invention, the light source is a fiber optic light source and a pair of achromatic lenses are used to focus the illumination on the substrate.

In another aspect of the present invention, further steps of oxidizing at least one sample reservoir to form an oxidized sample reservoir and etching the oxidized sample reservoir to form a double etched sample reservoir are included.

In a preferred embodiment of that aspect, the oxidizing step is performed with O₃, and the etching of the oxidized sample reservoir is performed with a solution containing HF.

Another aspect of the present invention contemplates a method wherein the etching is performed for about 1-2 minutes while illuminating the substrate with a light intensity of about 20-50 watts per square centimeter.

Another aspect of the invention contemplates a method of assaying organic compound analytes for a desired physical property in samples. Such a method comprises the steps of:

providing a n-type semiconductor substrate having at least one double etched sample reservoir defined therein;

providing a sample having at least one organic compound analyte;

providing a source of radiation;

introducing the sample containing at least one analyte to the double etched sample reservoir to adsorb the sample to the reservoir free of matrix material;

irradiating the sample reservoir, typically using a pulsed laser, so that the sample reservoir absorbs the radiation and desorbs the analytes;

analyzing the desired physical property of the desorbed and ionized analytes.

In a preferred embodiment of the method of assaying, the number of low mass background ions generated by the substrate when irradiated is substantially less than the number of ions generated by the sample.

In a preferred embodiment of the invention, the desired physical property is mass, and the analysis of the desorbed and ionized analyte comprises measuring the mass to charge ratio of the analyte.

In a still further embodiment of the invention, the substrate has a plurality of sample reservoirs, and a plurality of samples are provided with each sample being introduced to a respective sample reservoir, and wherein further the plurality of sample reservoirs are irradiated, and the analytes desorbed and ionized from each sample reservoir are separately analyzed for the desired physical property.

In yet another embodiment of the present invention, the desired physical property is mass, and the analyzing the desorbed and ionized analyte comprises measuring the mass to charge ratio of the analytes, wherein each sample is illuminated and analyzed in a period of less than about 5 seconds.

In another embodiment of the invention, the samples comprise an enzyme or protein that optionally can have a molecular weight (MW) of greater than about 5,000 Daltons (Da).

In yet a further embodiment of the invention, at least one analyte comprises a conventional tag and the analysis of the analyte measures the conventional tag along with the analyte as a whole, and does not measure the conventional tag separately.

In another embodiment of the invention, the sample comprises a plurality of analytes, which are substantially simultaneously desorbed and ionized upon irradiation of the sample reservoir.

The present invention has several benefits and advantages.

The present invention also offers a high-throughput, sensitive and accurate assaying tool for assays necessarily using a large number of measurements such as studies of inhibitor libraries and enzyme activity. Such reactions can also be advantageously studied because the present invention permits direct study of the reaction mixtures of these and other organic-compound containing mixtures of chemicals that are potentially reactive with each other without prior separations or treatments.

The present invention also provides substrates that have low levels of low mass interference with the laser desorption measurements.

Another advantage is that the present invention does not require use of an internal standard, chromophore, radiolabel or other conventional tag and thus provides a viable alternative to existing mass spectrometry and spectroscopic approaches. An assay that does not require pretreating the components of a sample or adding separate monitoring species to a sample provides greater flexibility in the selection of chemical species to be studied and increased speed because time-consuming steps are eliminated.

Still further benefits and advantages of the invention will be apparent to the skilled worker from the discussion that follows.

### BRIEF DESCRIPTION OF DRAWINGS

In the drawings forming a portion of this disclosure:

FIG. 1A is an illustration of a sample plate having a substrate with sample reservoirs of the present invention;

FIG. 1B is a scanning electron micrograph of a porous silicon surface region suitable for practice of the present invention;

FIG. 2 is a schematic of apparatus used in a time-of-flight laser desorption mass spectroscopy analysis of the present invention;

FIGS. 3A-C illustrate the use of sample plate having 100 sample reservoirs in assaying a plurality of species, FIG. 3A illustrates the size and arrangements of the sample reservoirs in a substrate embodying the present invention, FIG. 3B shows a variety of small drug molecules that give clear mass spectroscopic signals with the claimed invention, FIG. 3C shows a plurality of mass spectra for one the small drug molecules, cimetidine, and how reproducible such measurements are without an internal standard;

FIG. 4 is a schematic of an apparatus used to photochemically etch substrate material to produce substrates;

FIGS. 5A-B illustrate the application of the present invention to enzyme inhibitor assays, FIG. 5A shows the mass spectra of the reactant and a product of an acetylcholinestrase enzyme reaction, while FIG. 5B shows the ratio of reactant to product after reactions for a library of 100 candidate inhibitors;

FIG. 6A shows the metabolism path of L-phenylalanine to L-tyrosine, while FIG. 6B shows the mass spectra of those species adjacent to deuterated versions constituting a test for the presence or absence of the activity of phenylalanine hydroxidase in a sample; and.

FIGS. 7A-B are a comparison between MALDI and assays of the present invention in assaying digested BSA, where FIG. 7A shows the mass spectrum of 1 femtomole of the BSA digest studied via MALDI and FIG. 7B shows the results from 0.5 femtomoles on a substrate made in accordance with the present invention.

### DETAILED DESCRIPTION OF THE INVENTION

Although the present invention is susceptible of embodiment in various forms, there is shown in the drawings and will hereinafter be described a presently preferred embodiment with the understanding that the present disclosure is to be considered an exemplification of the invention and is not intended to limit the invention to the specific embodiments illustrated.

It is to be further understood that the title of this section of the specification, namely, “Detailed Description of the Invention” relates to a requirement of the United States Patent and Trademark Office, and is not intended to, does not imply, nor should be inferred to limit the subject matter disclosed herein or the scope of the invention.

The present invention relates to improving the performance of high throughput mass spectrometry assays. These high throughput assays can be facilitated by improved optical and chemical techniques for photochemically etching porous semiconductor substrates, such as porous n-type silicon substrates, that result in sample reservoirs that are more accurately located and better formed. Further, the reservoirs can be formed in such a way that each of a plurality of reservoirs can provide reasonably reproducible results from reservoir to reservoir. It has also been found that the substrates can achieve improved results in on-chip reaction monitoring of reaction mixtures in that the substrates can simultaneously achieve accurate, reproducible measurements of a plurality of analyte species from a single reservoir in one step. These measurements can be performed with very low levels of interference from substrate or technique induced low mass interference. Further, these measurements are sensitive in that they generally require less than 1 picomole of sample to achieve reliable results.

Laser desorption/ionization mass spectrometers equipped with automated multisampling capabilities that can accept samples plates having a plurality of locations where samples can be introduced are commercially available. The embodiments illustrated and described hereinafter are configured to be handled by commercial mass spectrometers in the same manner as MALDI plates. However, despite such illustration, the present invention is not limited to MALDI plate configurations.

The automation of these kinds of analyses are generally designed to search for an analyte signal from each sample location. These analyses are driven by a computer-controlled procedure to monitor for the analyte ion signal as a function of laser position within each sample location and as a function of laser intensity. To accomplish this the computer workstation automatically adjusts laser intensity and searched the sample well until a signal (within the specified mass range and intensity threshold) was obtained. Each parameter (laser intensity, step size in well, and m/z range) can be based on a preselection of autosampler options from a manual analysis of analytes in order to minimize the analysis time and to maximize the signal quality.

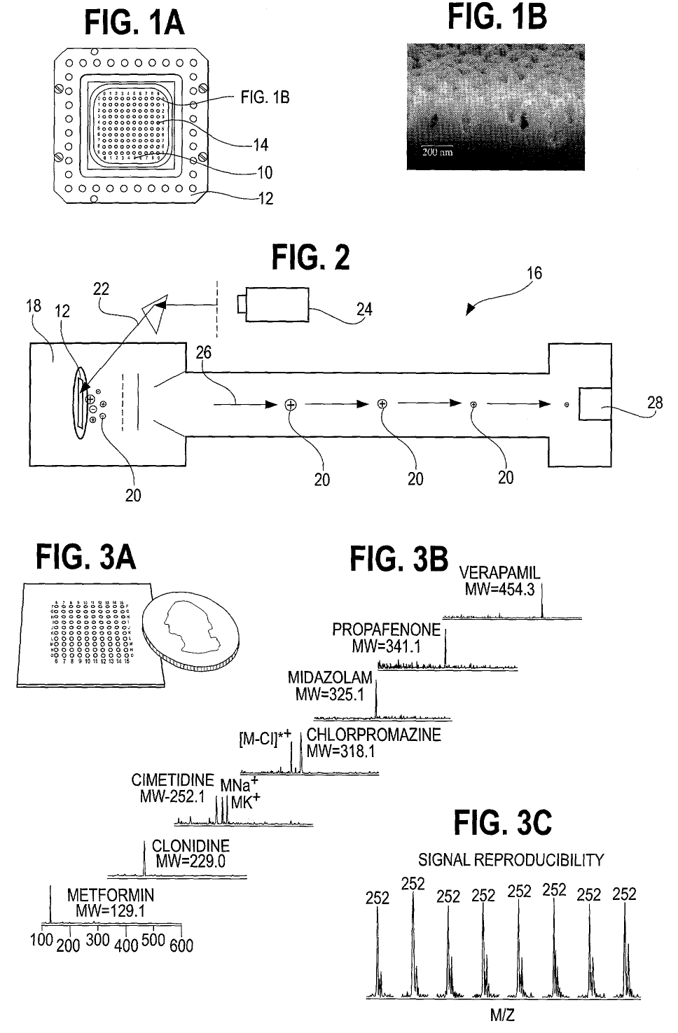

Referring to FIGS. 1-2, an overview of the present invention as implemented for use in, but is not limited to, a time of flight mass spectrometer. FIG. 1A illustrates a photopatterned substrate 10 attached to a modified commercial MALDI sample plate 12. The substrate 10 will have at least one sample reservoir 14, and preferably a plurality of sample reservoirs 14 formed therein. Referring to FIG. 1B, a scanning electron microscope image shows one morphology of the surfaces used in the specific discussed examples of the invention which are formed from porous n-type silicon. Solutions can be deposited onto sample reservoirs 14 by an automated sample handling robot (not illustrated) and allowed dry before being loaded into a mass spectrometer for analysis.

The deposited solution can comprise a solvent and a sample where the sample can comprise one or more analytes, or a number of analytes that may or may not be known. A solution may even comprise a sample that changes over time. One example of a sample that would change over time would be a reaction mixture proceeding towards completion. The sample in solution could comprise all reactants at one time, comprise all products at another time, and comprise a mixture of reactants and products at times in between. The present invention is especially useful for analyzing samples having a plurality of bioactive, biochemical, and other organic compounds. Such compounds, and others, are often subject to substantial signal suppression using other techniques, such as ESI, rendering the identification of even single-analyte samples difficult, and multiple analyte samples geometrically or exponentially so.

FIG. 2 shows a schematic of a laser desorption mass spectrometer 16 that can be used in mass spectrometric assays. While mass spectrometry is one beneficial use of the present invention, other assays such as spectroscopy that can be performed on ions can benefit from the present invention, and the present invention can also be applied to other assays that can study ions such as absorption spectroscopy. It will be understood by those of ordinary skill in the art that the present invention does not rely on chromphores, fluorophores, radiolabels or other conventional tags and the like to conduct measurements. However, such conventional tags may be present in a sample for reasons unrelated to the measurements of the present invention, including mass spectroscopy. The presence of such conventional tags in a sample should not be confused with reliance of a measuring technique on such conventional tags. While the present invention does not rely on such conventional tags to conduct measurements, it can measure by other means, the presence such conventional tags to the extent they are present in an analyte and measured with the remainder of the analyte.

Continuing with FIG. 2, in performing an assay, the sample plate 12 is placed in a source chamber 18 of a commercial laser desorption time of flight instrument. In the source chamber 18, sample ions 20 can be desorbed and ionized from the sample reservoirs of the substrate with a laser pulse 22 from a laser 24. In the case of mass spectrometry the ions are subsequently accelerated 26 into a mass analyzer 28. The analysis instrument can be equipped with automated, multisampling capabilities to facilitate data collection and analysis as discussed above in order to perform high throughput experiments.

To facilitate automated assays of a plurality of samples, such as the previously discussed autosampling mode of commercially available MALDI spectrometers, substrates can be manufactured with accurately photopatterned sample reservoirs to allow the samples spotted thereon to be measured efficiently. The sample reservoirs are preferably of a consistent shape, have a consistent size on the surface, and have a consistent depth into the substrate. The sample reservoirs can be positioned with a spacing greater than the footprint of the radiation source used to ionize the sample to avoid the desorption and ionization of adjacent samples. In the case of typical MALDI mass spectrometer instrumentation, a focused laser beam having a footprint of about 50-150 μm is typical, and sample spots should be spaced at least that far apart as measured edge to edge.

The automation of the DIOS analyses is designed to search for an analyte signal from each sample spot by monitoring signal strength as a function of laser intensity and laser position. The starting point for the relevant parameters (laser intensity, step size in each “well”, and m/z range) is established manually for each plate. The laser intensity was initially set at the minimum level necessary for desorption and then allowed to increase by approximately 10 μJ/pulse per step until an acceptable data signal (signal-to-noise >100, within the specified mass range) was acquired, up to a maximum of 50 μJ/pulse. If no signal was observed the laser beam was repositioned on the well and DIOS-MS analysis resumed at the lower laser power. To adjust the laser position on the MALDI sample plate a pre-programmed spiral search pattern was used which began in the center of each circular well and spiraled outward in 0.2 mm increments.

In practice the automatic adjustments of laser position were never triggered since good (and highly reproducible) spectra were always obtained on the first try due to the uniform sample spots (or reservoirs) typical for DIOS plates. FIG. 2C shows that the present invention is very successful in producing reproducible results as is shown by the low standard deviation of signal intensities of the same sample (50 pmol of cimetidine) deposited on different reservoirs was less than 20%.

FIG. 3A illustrates a DIOS substrate manufactured to allow the accurate allocation of 100 sample reservoirs per wafer. The substrate is shown adjacent to a quarter to provide a sense of scale. DIOS substrates allowing the accurate allocation of 900 sample spot per wafer have also been made, but aspects of the present invention can be practiced with any number of reservoirs. It should be noted that the illustrated sample reservoirs (which typically appear to the naked eye as darkened areas circles on an etched silicon wafer) are not “wells” in the sense of being completely empty, but etched regions of porous semiconductor containing pores, wherein the pores are preferably approximately 70-120 nm in diameter, are spaced about 100 nm apart, and have a pore depth of up to about 200 nm.

The sample spots can be any size appropriate to the footprint of the light used to desorb and ionize the sample for a particular light source, and the methods intended. If the sample is deposited in an even fashion on the sample reservoir, the footprint of the illumination can be confined to be substantially within the sample spot, and therefore achieve consistency spot-to-spot in desorption and ionization. Currently favored sample reservoirs on currently manufactured substrates have well sizes of about 0.5 to 2.5 mm, which are much larger than the footprint of a typical focused laser spot used for MALDI. The sample being much larger has the advantage that multiple measurements can be made from the same sample spot with some reproducibility. Alternatively, if the quantity of sample deposited is reasonably controlled, the footprint of the illumination can be much larger than the sample spot to achieve absorption and ionization from the entire sample spot. As a further alternative, the reservoir size can be about the same size as the footprint of the intended illumination, but accurate aiming of the laser to the sample and accurate deposition is sample quantity is necessary to achieve reproducible results.

Substrates for the present invention can be manufactured by illumination or irradiation through a simple mask during electrochemical etching. The combination of illumination and etching permits effective photopatterning of sample reservoirs on the substrate. The etching rate on n-type substrates such as silicon is fairly dependent on light intensity, in comparison to p-type silicon substrates. This dependence permits accelerated manufacture of substrates from n-type silicon.

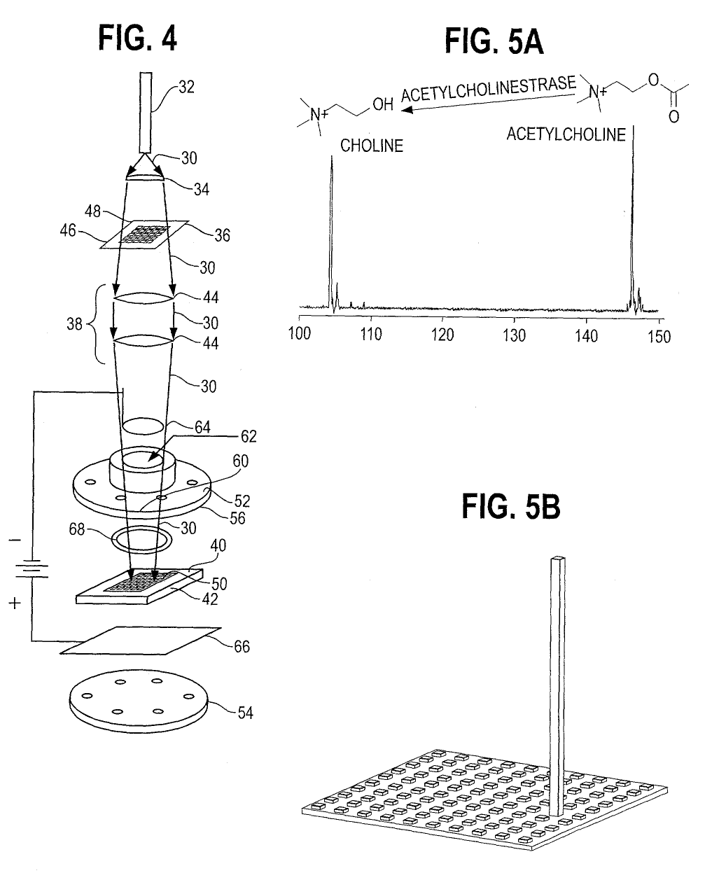

Referring to FIG. 4, in order to create patterns on the substrate, the light 30 from a light source 32 is passed through a condenser lens 34, a printed mask 36 and a focusing lens assembly 38 on the way to the surface 40 of the substrate 42. This simple apparatus can reproducibly produce sharply defined sample reservoirs. While other arrangements of optical elements known to those of ordinary skill in the art can provide suitably formed sample reservoirs, it has been observed that the use of two focusing lenses 44 can provide superior results when compared to apparatus that uses only one focusing lens 44.

One light source 32 that can be used is a model I-150 fiber-optic light source available from Coherent, Inc. equipped with a 150-W tungsten filament bulb. A condenser lens 34 that is integral to the recited light source 32 accepts light from the light source and channels the illumination (or radiation) towards the mask 36. In one embodiment a lm flexible light guide, part number A42-347, with an adjustable lens on the end can be used, can be obtained from Edmund Industrial Optics, of Barrington, N.J. While the use of a condenser lens 34 is optional, by gathering more light from the light source 32 and directed it towards the mask 36, it reduces the strength of the light source 32 needed to achieve good results.

The light 30 directed from the condenser lens can be projected onto a mask 36. The mask 36 can be made of materials that comprise opaque (or light absorbing) sections 46 and transparent (or light transmitting) sections 48. The transparent sections 48 of the mask 36 will define the pattern 50 of sample reservoirs to be formed, while the opaque sections 46 will define the surrounding substrate sections. The pattern 50 on the final substrate surface 40 can be easily changed by using different masks 36 during etching. Suitable opaque materials include, but are not limited to, plastic, metal, wood, paper, inks, and toners. One flexible technique for the printing of masks, is to print on standard transparencies using a laser printer. In that case the transparent portions 46 of the mask defined by the absence of toner or ink will correspond to where the sample reservoirs will form, and the opaque portions 48 of the mask will correspond to where the portions of the substrate 42 that surround the sample reservoirs will be.

The focusing lens assembly 38 accepts the patterned light 30 that has passed through the mask 36. In the case of using a matched pair of lenses 44, achromatic lenses suitable for the practice of the present invention are sold by Coherent, Inc. as part number 23-9723 having a focal length of 80 mm and a diameter of 50 mm. The choice of focusing lenses 44 depends on the selection of light source 32, mask 36, and condenser lens 30. Other equivalent lens combinations using unmatched lenses 44, or positioning the lenses 44 differently within an overall system can be matched to achieve the same result.

The focusing lenses 44 should be positioned to form a clear, sharp, image on the surface of the substrate 42. Those of ordinary skill in the art will be familiar with techniques for holding and positioning lenses 44 to create a sharp, stable image. The lenses 44 can cooperate to scale the pattern formed by the mask 36 up in size or down in size, with a corresponding and opposite result in light intensity present on the surface 40 of the substrate 42. The performance of the optical system as a whole is an important part of its operation. The present invention is embodied when the system projects about 20-50 mW/cm² onto the substrate while forming a clear image of the locations where the sample reservoirs are to be formed by etching the substrate 42 to form a porous substrate.

Continuing with FIG. 4, the substrate material 42 can be a semiconductor, but other materials having the features described herein are also contemplated by the present invention. A substrate 42 of the present invention will be able to absorb light to desorb and ionize analytes deposited thereon. Preferably, the substrate 42 operates without forming adducts with the sample, but in certain applications such adduct formation could be desired, such as where adduct formation might be necessary to maintain molecular stability for a measurement. A substrate 42 material of the present invention will be capable of providing reasonable (plus or minus about 20%) reproducibility of results from sample reservoir to sample reservoir made either using the same techniques, or by achieving the same or similar pore sizes and depths. A substrate material of the present invention can also have a low background (interference) ion contribution.

It has been observed that n-type semiconductor material demonstrates a stronger dependence on light intensity than p-type semiconductor material during etching. Accordingly, n-type silicon can be photopatterned more rapidly than p-type silicon because the n-type silicon is more affected by the increased light intensity than p-type silicon. The faster photopatterning has been observed to produce sharper reproducible patterns on n-type silicon substrate surfaces. In particular, photopatterning of the DIOS substrates is advantageous in order to utilize automated modes during sample deposition and data acquisition.

High performance substrates 42 can be manufactured from n-type <100> low-resistivity silicon wafers having about 0.005-0.02 Ω-cm resistivity. Wafers having a thickness of about 0.5 mm can provide a substrate 42 material thin enough to easily be embedded in a modified MALDI plate while providing sufficient depth for the formation of operable sample reservoirs.

Porous semiconductor substrates 42 can be prepared by electrochemical etching of a substrate material in a HF/EtOH solution under illumination. These substrates 42 can be prepared by electrochemical etching in a cell made of a suitable inert material, including, but not limited to, TEFLON brand polytetrafluoroethylene (PTFE) available from many vendors of products using PTFE from Dupont of Wilmington, Del. The cell can be made of two sections 52, 54 that can be held together by various means (not pictured) known to those of ordinary skill in the art including, but not limited to, bolts, screws, clamps and their equivalents. Means for holding portions 52, 54 of the cell together are preferably made of an inert material that will not be degraded by the etching solvents, including, but not limited to, plastics, including polypropylene.

As shown in FIG. 4, the first, or upper portion of the cell 52 can have a bottom surface 56 suitable for forming a seal, holes 58 for securing the portion to other objects including the second portion 54 of the cell, and a wall portion 60 for defining a cell opening 62 that can serve as an etching reservoir or cell. The Etching reservoir or chamber to be defined by the first or upper portion of the cell 52 can be transparent to the light from the light source 32 to be used to promote and/or define the etching occurring in the etching cell and should be made to be inert with etching solution.

The cell opening portion 62 of the upper cell can be sized to fit over the surface 40 of the substrate 42 material to be etched while permitting light to reach the substrate material from the optical assembly above. A first electrode 64, which is one of the anode or cathode, is positioned in the cell cavity 62, and a second electrode 66 which is the other of an anode or a cathode, is placed under the substrate 42 to provide electrical contact to the substrate and serve as a counter electrode to the first electrode 64. The first electrode 64 is positioned in the cell cavity and is formed and positioned in such a way as to permit the light coming from the mask to illuminate the upper surface of the substrate material. Generally, the first electrode 62 will be 1-2 mm above the surface 40 of the substrate 42 and immersed in the etching solution. One method of doing so is to form the first electrode 62 as a ring having a diameter large enough to encompass all of the sample reservoirs to be formed. Optionally, an improved seal between the cell and the substrate 42 material can be formed by using a sealing means 68 such as an O-ring, gasket, or their equivalents or other sealant placed between the upper portion 52 of the cell and the substrate 42 material. Preferably, the sealing means 68 is inert to etching solutions. The second portion of the cell, or bottom portion 54 can then be connected to or affixed to the first portion 52 to maintain contact between the second electrode 66 placed under the substrate 42 material and the substrate material.

In one embodiment of the present invention where n-type silicon is being etched, the second electrode 66 is a gold foil, preferably 0.1 mm thick, placed under the silicon wafer 42 to provide electrical contact as an anode, and a first electrode 64 made of platinum wire is positioned in the cell as the cathode. As will be appreciated by those of ordinary skill in the art, other materials can be substituted, with materials that will be inert under the etching conditions being preferred. The parameters appropriate for the etching of particular materials, and exhibiting the proper anodic or cathodic character without degradation will be understood by those of ordinary skill in the art by referring to electrochemical reference materials.

An etching solution can be introduced to an etching cavity 62 where it will contact the substrate 42. One etching solution that can be used is a HF/EtOH solution. When etching n-type silicon wafers, a solution of about (proportions) can be used with a solution of about 25% HF/EtOH being frequently used. It is has been observed that solutions of about 15-35% all operate reasonably in etching the silicon embodiment of the present invention.

The etching is done under illumination, preferably from a white light source 32, and even more preferably a strong white light source. As discussed above, the optical system can be configured to deliver from about 20-50 mW/cm² of illumination to the surface as measured by a radiometer detector (model IL1405, INTERNATIONAL LIGHT, INC., Newburyport, Mass.) or equivalent. This is in comparison to a light intensity of greater than about 1 mW/cm² generally needed to get minimal DIOS function from a silicon substrate. Such a measure is intended to reflect the strength of illumination generated by a generally while color of light as provided by a commercial tungsten filament incandescent bulb. The present invention also contemplates equivalent amounts of light generated by other means, or measured by other means known to those of ordinary skill in the art.

Illumination for about 1-2 minute at a constant current density of 4 MA/cm² can produce good sample reservoirs. Such an etching duration and low current density can provide substrates having the proper reproducibility, background ion, and sample desorption and ionization characteristics when accompanied with the light intensity of 20-50 mW/cm² of illumination to the surface of the substrate. Etching for shorter times at higher light intensities, or etching for longer times at lower light intensities can have undesirable results and fail to produce suitable substrates for high-throughput studies. In particular, etching for more than 5 minutes at the recited current and light intensity can produce brittle substrates that present increased low mass background interference.

The sharp reproducible patterns formed using the optical and etching systems above help facilitate high throughput analyses. First, with sharp reproducible patterns, the automated instrumentation can readily and reproducibly find and excite the sample spots on the substrate. Second, with an adequately and accurately formed pattern, no internal standard is needed to get reasonable reproducible intensity measurements. Experience has shown that well formed patterns can result in intensity variations from sample spot to sample spot of less than 20%.

After etching, the substrates can be removed from the cell and oxidized by O₃ and then treated with 5% HF in H₂O, which has been found to provide more regular pore morphology and better high throughput assay performance.

Laser desorption/ionization measurements can performed in a PerSeptive Biosystems (Framingham, Mass.) Voyager STR time-of-flight reflectron mass spectrometer. The measurements discussed hereinafter in the examples were performed on such an instrument with delayed extraction. Substrates made from n-type silicon using the preferred modes of illumination and etching were attached to the MALDI target plates using conductive carbon tape. Samples were irradiated with a nitrogen laser operated at 337 nm at 5 Hz (3 nanosecond pulse duration) and attenuated with a neutral density filter. Ions produced by laser desorption were energetically stabilized during a delayed extraction period of 150 nanoseconds and then accelerated through the linear time-of-flight reflectron mass analyzer with a 20 kV potential pulse. The instrument was equipped with automated, multisampling capabilities to facilitate data collection and analysis.

Analytes from the libraries were typically dissolved in water or water/methanol/DMSO (54.5%, 45%, and 0.5%). Freshly etched DIOS surfaces are hydrophobic allowing aqueous solutions to bead and dry in a relatively uniform manner, samples dissolved in nonpolar solvents are less ideal since they spread across the hydrophobic porous silicon wafer. Aliquots (0.1-0.5 μL; containing 1 to 500 picomoles of analyte) were deposited directly onto the porous silicon surfaces and allowed to dry before DIOS-MS analysis.

Generally, sixteen scans were averaged to obtain adequate spectra for each sample On average the total time spent for each sample spot analysis was 5 seconds. This included acquisition time for averaging 16 scans, a delay for firing the laser, and repositioning of the sample plate. It takes less than 10 minutes to finish the analysis of a 100-sample DIOS substrate.

The following examples demonstrate use of DIOS-MS in the high-throughput analysis of small molecules (less than 3000 Da) and as an accurate quantitative assay that does not require a chromophore or radiolabelling for inhibitor libraries. It also demonstrates measurements in the presence of proteins or enzymes that can have a mass of greater than 5,000 Daltons. Mass spectral data can currently be acquired at a rate of one sample per 5 seconds where the analysis rate is limited by instrument hardware (data acquisition system and translation platform) rather than any inherit limitation in the DIOS-MS methodology. Instrumentation upgrades such as faster x-y translation motors, a redesign of the software and a faster digitizing scope can provide for a 5-fold enhancement in acquisition rate to greater than one sample per second (˜100,000 samples per day). With such improvements, DIOS-MS is of great use as an analytical tool in combinatorial applications, particularly in the discovery of novel enzyme inhibitors. The utility of DIOS-MS in proteomics is also demonstrated because of the ease with which assays can be developed for different enzymes. Since the only prerequisite for the assays of the type discussed herein is an ionizable substrate (or product) it can be applied to virtually any enzyme for monitoring inhibition or characterizing activity of novel enzymes.

The examples cited herein are representative and not an exhaustive listing of all high-throughput assays done with the present invention. Some assays are not recorded here were of proprietary materials, and while interesting in themselves, do not add to the appreciation of the invention itself.

### EXAMPLE 1

### High Throughput Small Drug Molecule Assay

Referring to FIGS. 3A-C, in order to demonstrate the general applicability of DIOS-MS, compounds from a drug discovery library were analyzed with DIOS-MS in a total analysis time of 8 minutes. For these assays, the DIOS plate was then loaded into the mass spectrometer and analyzed using a computer-controlled algorithm. The results in the assays were comparable to what a high-throughput Supercritical Fluid Chromatography/Atmospheric Pressure Chemical Ionization—Mass Spectrometry (SFC/APCI-MS) analysis would provide in 2-4 hours. Although DIOS presently provides for no chromatographic separation of components of mixed samples, the results are useful in both pre- and post-preparative confirmation modes. In reviewing the structures (some proprietary), it was noted that the ESI ionizable molecules all ionized well by DIOS, as 85% of the compounds that ionized using APCI-MS were also ionized by DIOS-MS. There were several compounds that did not appear when analyzed by APCI LC/MS (Atmospheric Pressure Chemical Ionization—Liquid Chromatography/Mass Spectrometry) but were detected using DIOS-MS.

Referring to FIG. 2A, a photopatterned DIOS chip adjacent to a quarter of similar size. The 10 by 10 array of dark spots are porous Si photopatterned onto the Si wafer using photo-enhanced electrochemical etching. To demonstrate the high-throughput capability of DIOS-MS, 0.5 AL of a 100 μM solution containing a solution of each of several drug molecules were deposited on each sample reservoir by pipette and allowed to dry as shown by reference to FIGS. 2A-B. FIG. 2B shows DIOS mass spectra of non-proprietary small drug molecules metformin, clonidine, cimetidine, chlorpromazine, midazolam, propafenone and verapamil. Each porous silicon spot has about 50 pmol of sample deposited on it. The samples were deposited, and the experiments were conducted without any internal standard present. The automatically collected spectra, which are of the same quality as obtained by manual operation of the instrument, match or exceed the standards set by electrospray ionization.

Each spectrum shown is an average of over 16 laser shots and required, on average, 5 seconds to obtain for a rate of 720 samples per hour. The laser repetition rate is 5 Hz. The speed of the assay is in part limited by the apparatus's requirement for about 1 second to move from one sample spot to the next and 4 seconds to initiate laser firing and data collection.

FIG. 2C shows DIOS-MS spectra of 8 distinct sample spots containing 50 pmol cimetidine each. The standard deviation for the signal intensity variation was below 20%. The good intensity reproducibility is due to the homogeneous sample reservoirs in the substrate. Each spectrum shown is an average of over 16 spectra recorded in different locations from the same porous Si spot.

### EXAMPLE 2

### High Throughput Acetylcholinesterase

Inhibition Assay

An automated DIOS system has been applied as a quantitative, high-throughput screen for inhibition of enzyme activity, a common measurement in drug discovery applications. FIG. 5A illustrate how the activity of Acetylcholinesterase (AChE), which catalyzes the hydrolysis of acetylcholine to choline and is therefore an important pharmaceutical target, was examined. Mass spectra of reaction mixtures were spotted in the sample reservoirs of a DIOS substrate having 100 reservoirs. The reaction between an enzyme solution and an excess of the acetylcholine substrate reached completion within 15 minutes when performed at optimal conditions (pH 8, 37° C.). An AChE assay implemented as a DIOS-MS analysis involved monitoring inhibition of over 100 compounds including known inhibitors. The inhibition of this process was examined by incubation of candidate small molecules with the enzyme and substrate for 30 minutes at pH 8, 37° C., followed by measurement of the acetylcholine/choline ratio by DIOS-MS. Acetylcholine/choline ratios are measured by DIOS-MS at a rate of every 5 seconds per every sample.

FIG. 5A shows how the enzymatic production of choline (m/z 104) from the acetylcholine substrate (m/z 146) and AchE is monitored. FIG. 5B shows the substrate/product ratio mapping of the individually measured components by high-throughput DIOS-MS. Known AChE inhibitors (tacrine and huperzine) could be picked out by the observation of high acetylcholine/choline ratios; no false positives or false negatives were observed among the 100 compounds examined. The current throughput of such enzyme inhibitor screening is approximately 8 minutes for a set of 100 compounds.

### EXAMPLE 3

### Other High Throughput Enzyme Activity Assays

The ability for DIOS to rapidly monitor the inhibition of other enzyme-catalyzed reactions was also investigated including a phopholipase and four different proteases. The DIOS assays for all of the enzymes were each developed within a couple of hours and the subsequent monitoring of inhibition was readily achieved. For instance, potential inhibitors for phospholipase A2 were examined as a function of the specific A2 catalyzed reaction that involved the removal of the sn-2 fatty acyl chain from a phosphotidylcholine lipid. The library compounds tested against phospholipase A2 did not reveal any new small molecule inhibitors yet the viability of the approach was demonstrated by inhibition of A2 by exposure to organic solvents or acid. DIOS was also applied to four different proteases including trypsin, endoproteinases Arg-C, Lys-C, and Glu-C with bovine serum albumin (BSA).

For the proteolytic assay bovine serum albumin was incubated overnight at 37° C. in 5 mM ammonium citrate (pH 7.5 for tryptic digest and pH 8.5 for the endoproteinases). The reactions reached completion within 18 hours. Samples were deposited on optimized DIOS substrates under etching conditions: 50 mW, 2 min, and 5 mA. Mass spectral data of BSA digested with trypsin and the endoproteinase enzymes showed peptides peaks in the range 500-2500 Da. Known inhibitors obtained from Sigma including aprotinin, sulfanilamide, 4-acetomidaphenol, nystatin, chloropram, phenoxymethyl penicillinic acid, cimetidine, and furosemide were tested. Prior to the addition of BSA (100 nM and 2 μM) and ammonium citrate buffer solution, the enzyme and the inhibitor mixture were incubated for at least 30 minutes at 4° C. The proteolytic digests were incubated at 37° C. and the digestion was monitored using DIOS-MS after 2, 5, and 18 hours.

### EXAMPLE 4

### High Throughput Phenylalanine Hydroxylase

Assay To Diagnose Phenylketonurea

The absence of phenylalanine hydroxylase (PheOH), which converts phenylalanine to tyrosine, results in the metabolite disease known as Phenylketonurea (PKU). DIOS has also been implemented as a high throughput assay for phenylalanine hydroxylase (PheOH) activity which is associated with the disease Phenylketonurea (PKU). PKU is an inherited, metabolic disorder (15) that can result in mental retardation if untreated at birth and is caused by a deficiency of the enzyme PheOH which is necessary to convert phenylalanine to tyrosine. The goal in developing this assay is to screen thousands of mutant PheOH proteins for the discovery of a proteolytically stable form of the PheOH enzyme which will be stable against degradation by the gastrointestinal (GI) environment during oral administration.

A current approach for screening for PKU at birth is electrospray ionization tandem mass spectrometry with a throughput of a sample every 120 seconds. (16, 17) Current, more rapid, PheOH activity assays are based on calorimetric or radioactive detection are not as sensitive or efficient as DIOS-MS. Although pure Tyr and Phe standards yield strong signals in DIOS under both positive and negative ion modes, we found that in the PheOH assay negative ion mode produces less low mass interference from the incubation mixture than positive mode. As shown in FIG. 4, a spectrum of the PheOH reaction product have a peak at m/z 164 (corresponding to unreacted L-phenylalanine) and a peak at m/z 180 (corresponding to enzymatically-produced L-tyrosine).

Phenylalanine hydroxylase (PheOH) assays on DIOS-MS analysis involve mixing mutant forms of recombinant human-PheOH purified protein (0.06 mg/ml) or mutant PheOH over-expressed E. coli lysate (1% of the final volume) with 25 mM ammonium bicarbonate buffer (pH 7.4), 0.1 mg/ml bovine catalase and 1 mM L-phenylalanine. This mixture is incubated at 25° C. for 5 minutes followed by 1M Fe²⁺ addition to the reaction for 1 minute at 25° C. The hydroxylation reactions are started with the addition of 6 mM dithiothreitol (DTT) and 75 μM cofactor (6R-BH₄) or 500 μM synthetic cofactor 6-methyltetrahydropterin (6MPH₄). Reaction mixtures are allowed to react for 30 min at 37° C., and are then stopped with the addition of acetic acid. Samples (0.5 μL aliquots) were deposited onto a DIOS substrate, allowed to dry, and analyzed by DIOS-MS.

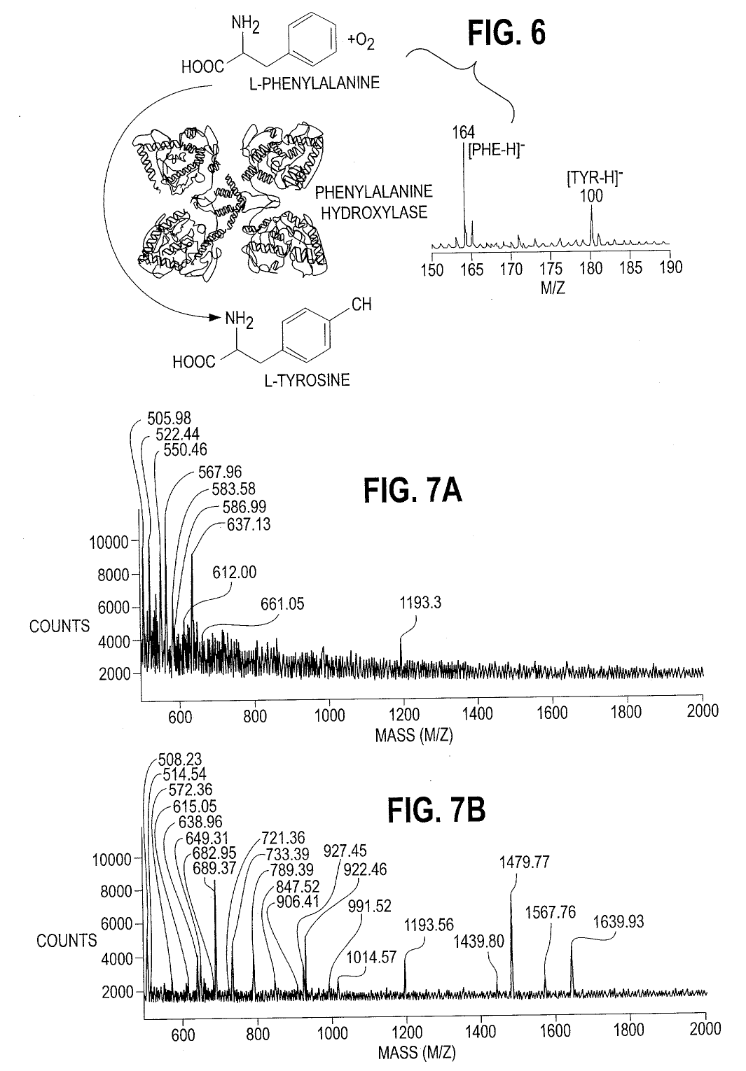

As shown in FIG. 6, by using an internal standard for each analyte of interest (deuterium-labeled L-Phe and L-Tyr, ²H₅-ring-Phe, ²H₄-ring-Tyr, respectively) it is possible to quantify the ratio of transformation of L-Phe to L-Tyr and thereby calculate the specific activity of the protein by varying substrate concentration and measuring product formation for a fixed reaction time. Once preliminary screening using this assay has identified positive clones, more detailed kinetic and stability studies (including Vₘₐₓ and Kₘ determinations, binding constants of substrates, proteolytic stability, pH dependence of activity, temperature-dependence of activity) can be performed on these PheOH species. Finally, the ability to directly measure the catalytic activity of enzymes expressed in lysates of E. coli without any time-consuming purification steps makes DIOS an excellent tool for large scale enzyme activity screening.

### EXAMPLE 5

### Comparison of MALDI and Improved DIOS for Proteomics

Mass spectrometry is quickly becoming an essential tool for proteomics due to its high sensitivity and accuracy, especially for protein identification. Proteins are often classified by functionality, but exact identification requires peptide mapping and sequencing. Proteolytic digestion of proteins combined with mass analysis and database searching allows for protein identification as well as post-translational modification characterization.

The sensitivity of MALDI and DIOS for protein identification is compared in FIGS. 7A-B. A BSA tryptic digest sample (1 femtomol/μL) following standard digest procedure is used as the testing sample. 1 μL of the digest solution was mixed with 1 μL of matrix solution (α-Cyano-4-hydroxycinnamic acid) for MALDI analysis, and 0.5 μL of the digest solution was used for DIOS analysis. FIG. 7A shows the mass spectrum of 1 femtomole of the BSA digest studied via MALDI and FIG. 7B shows the results from 0.5 femtomoles on a substrate made in accordance with the present invention. DIOS shows much higher sensitivity than MALDI for protein identification. The same comparison was performed on a variety MALDI instruments from different manufactures including Bruker, Kratos, Applied Biosystems, and Waters. Consistently, DIOS shows 5-10 times higher sensitivity than conventional MALDI on the improved DIOS chips.

From the foregoing, it will be observed that numerous modifications and variations can be effectuated without departing from the true spirit and scope of the novel concepts of the present invention. It is to be understood that no limitation with respect to the specific embodiment illustrated is intended or should be inferred. The disclosure is intended to cover by the appended claims all such modifications as fall within the scope of the claims.

Each of the patents and articles cited herein is incorporated by reference. The use of the article “a” or “an” is intended to include one or more.

### REFERENCES

1. Enjalbal, C., Martinez, J., Aubagnac, J. L. Mass Spectrometry Reviews 19, 105-111.

2. Kyranos, J. N., Cai, H., Wei, D. & Goetzinger, W. K. Curr. Opin. Biotechnol. 12, 105-111 (2001).

3. Leushner, J. & Chiu, N. H. Mol. Diagn. 5, 341-348 (2000).

4. Kang, M. J., Tholey, A. & Heinzle, E. Rapid Commun. Mass Spectrom. 14, 1972-1978 (2000).

5. Higton, D. M. Rapid Commun. Mass Spectrom. 15, 1922-1930 (2001).

6. Finn, M. G. Chirality (2002), in press.

7. Claus P., Honicke D & Zech T. Catalysis Today 67, 319-339 (2001).

8. Wang, T., Zeng, L., Strader, T., Burton, L. & Kassel, D. B. Rapid Communications in Mass Spectrometry 12, 1123-1129 (1998).

9. Wang, T., Cohen, J., Kassel, D. B. & Zeng, L. Comb. Chem. High Throughput. Screen. 2, 327-334 (1999).

10. Kang, M. J., Tholey, A. & Heinzle, E. Rapid Commun. Mass Spectrom. 15, 1327-1333 (2001).

11. Wu, J., Takayama, S., Wong, C. H. & Siuzdak, G. Chem. Biol. 4, 653-657 (1997).

12. Wei, J., Buriak, J. M. & Siuzdak, G. Nature 399, 243-246 (1999).

13. Shen, Z. et al. Anal. Chem. 73, 612-619 (2001).

14. Thomas, J. J., Shen, Z., Crowell, J. E., Finn, M. G. & Siuzdak, G. Proc. Natl. Acad. Sci. U.S. A 98, 4932-4937 (2001).

15. Scriver C. R., Kaufman S, Eisensmith R. C. and Woo S. L. C. “The hyperphenylalaninemias” Ch.27 in: Scriver C. R., Beaudet A. L., Sly W. S. and Valle D, editors, The Metabolic & Molecular Bases of Inherited Disease. (1997) CD-ROM. McGraw-Hill.

16. Donald Chace, John E. Sherwin, Steven L. Hillman, Fred Lorey, and George C. Cunningham Clin. Chem. (1998), 44(12): 2405-2409.

17. S. Bird, C. Turner, R. N. Dalton, The Society for the Study of Inborn Errors of Metabolism (SSIEM) 39th Annual Symposium, Abstract. Prague, Czech Republic, Sep. 4-7, 2001. J. Inher. Metab. Dis. 24 (2001) Suppl. 1, 13.

I claim:

1. A method of making improved substrates for desorbing and ionizing analytes comprising:
providing an n-type semiconductor substrate;
providing a light source;
focusing the illumination from the light source onto the n-type semiconductor substrate to result in at least one lit region on the n-type semiconductor substrate; and
electrochemically etching the n-type semiconductor substrate with a low current during illumination to form at least one sample reservoir on the substrate, each sample reservoir being formed at a respective lit region on the n-type semiconductor substrate.

2. The method of claim 1, wherein the substrate is silicon.

3. The method of claim 1, wherein the light source is a fiber optic light source and a pair of achromatic lenses are used to focus the illumination on the substrate.

4. The method of claim 1, wherein the electrochemical etching is performed at a constant low current of about 4 mA.

5. The method of claim 1, further comprising:
oxidizing at least one sample reservoir to form an oxidized sample reservoir;
etching the oxidized sample reservoir to form a double etched sample reservoir.

6. The method of claim 5, wherein the oxidizing step is performed with O₃, and the etching of the oxidized sample reservoir is performed with a solution containing HF.

7. The method of claim 1 wherein the etching is performed for about 1-2 minutes while illuminating the substrate with a light intensity of about 20-50 watts per square centimeter.

8. A method of making improved substrates for desorbing and ionizing analytes comprising:
providing an n-type silicon substrate;
providing a white light source;
masking the illumination from the strong light source to define a light pattern;
focusing the light pattern on the n-type semiconductor substrate to result in a plurality of lit regions on the n-type semiconductor substrate lit with a strength of about 20-50 milliwatts per centimeter squared;
electrochemically etching the n-type semiconductor substrate for 1-2 minutes at a current of about 4 milliamps during illumination to form a sample reservoir at each lit region;
oxidizing at least one sample reservoir to form an oxidized sample reservoir; and
chemically etching the oxidized sample reservoir to form a double etched sample reservoir.

9. A method of simultaneously assaying a plurality of organic compound analytes for a desired physical property comprising:
providing a n-type semiconductor substrate having at least one double etched sample reservoir defined therein;
providing a sample having at least one organic compound analyte;
providing a source of radiation
introducing less than one picomole of the sample containing to the double etched sample reservoir to adsorb the sample to the substrate free of matrix material;
irradiating the sample reservoir so that the sample reservoir absorbs the radiation and desorbs the analyte;
analyzing the desired physical property of the desorbed and ionized analyte.

10. The method of claim 9, wherein the sample is introduced by being deposited in a solution and dried.

11. The method of claim 9, wherein the substrate is a low resistivity silicon substrate.

12. The method of claim 9, wherein the number of low mass background ions generated by the substrate when irradiated is substantially less than the number of ions generated by the sample.

13. The method of claim 9, wherein the desired physical property is mass, and the analysis of the desorbed and ionized analyte comprises measuring the mass to charge ratio of the analyte.

14. The method of claim 9, wherein the substrate has a plurality of sample reservoirs, and a plurality of samples are provided with each sample being introduced to a respective sample reservoir, and wherein further the plurality of sample reservoirs are irradiated, and the analytes desorbed and ionized from each sample reservoir are separately analyzed for the desired physical property.

15. The method of claim 14, wherein the desired physical property is mass, and the analyzing the desorbed and ionized analyte comprises measuring the mass to charge ratio of the analytes, wherein each sample is illuminated and analyzed in a period of less than about 5 seconds.

16. The method of claim 9, wherein the sample comprises a protein or enzyme.

17. The method of claim 15, wherein the protein or enzyme has a molecular weight of greater than about 5,000 Daltons.

18. The method of claim 9, wherein at least one analyte comprises a conventional tag, wherein the analysis of the analyte measures the conventional tag along with the analyte as a whole, and does not measure the conventional. tag separately.

19. The method of claim 9, wherein the sample comprises a plurality of analytes, and the analytes are substantially simultaneously desorbed and ionized upon irradiation.
